(19) United States
(12) Patent Application Publication
(10) Pub. No.: US 2026/0114085 A1
(43) Pub. Date: Apr. 23, 2026

(54) CONDUCTING DEVICES GROWN ON INSULATING SUBSTRATES

(71) Applicant: PROSTAR TECHNOLOGIES INC., Orlando, FL (US)

(72) Inventor: Leo J. SCHOWALTER, Oviedo, FL (US)

(73) Assignee: PROSTAR TECHNOLOGIES INC., Orlando, FL (US)

(21) Appl. No.: 19/365,776

(22) Filed: Oct. 22, 2025

Related U.S. Application Data
(60) Provisional application No. 63/710,833, filed on Oct. 23, 2024.

(51) Int. Cl. H10H 20/825; H10D 62/40; H10D 62/852; H10H 20/01; H10H 20/817

(52) U.S. Cl. CPC H10H 20/825; H10D 62/40; H10D 62/852; H10H 20/0137; H10H 20/017; H10H 20/019; H10H 20/817

(57) ABSTRACT

A conducting device including a plurality of conducting layers, where at least a portion of the conducting layers have a graded material concentration across consecutive layers which produces a lattice mismatch within conducting layers; etched surfaces extending through conducting layers, where the etched surfaces create localized stress regions within the conducting layers—where at least a portion of the conducting layers are disposed on an substrate, and where the localized stress regions and the graded lattice mismatch are structurally configured to establish a boundary along which at least a portion of the conducting layers is separable from the substrate.

### PRIOR APPLICATION DATA

The present application claims benefit from prior U.S. Provisional Application 63/710,833, filed on Oct. 23, 2024, and entitled “ACHIEVING VERTICAL ELECTRONIC DEVICES WITH ALUMINUM GALLIUM NITRIDE SEMICONDUCTORS GROWN ON INSULATING ALUMINUM NITRIDE SUBSTRATES”, which is incorporated by reference herein in its entirety.

### FIELD OF THE INVENTION

The present invention relates generally to vertical electronic and opto-electronic systems, and more specifically to systems of pseudomorphic nitride semiconductor layers grown on insulating aluminum nitride (AlN) substrates.

### BACKGROUND OF THE INVENTION

The recent commercial introduction of high quality substrates has allowed the commercial production of Ultraviolet C (UVC; e.g., of wavelengths shorter than 275 nanometers) Light-emitting diodes (LEDs) with high performance. However, devices demonstrated so far have relied on lateral current injection because of the insulating nature of these substates.

To make a p-n junction device, an n-type material may be grown on the substrate first, followed by at least one p-n junction and then topped with p-type material. In order to make a p-n junction device, a mesa may be etched into the epitaxial layer so that it is possible to contact the n-type layer. In this geometry, current may be injected through the n-type contact and has to flow laterally under the device before it can flow vertically up though the p-n junction.

A lateral current flow geometry, however, may significantly increase the device's resistance (resulting, inter alia, in greater energy dissipation and lower efficiency, lesser light output, and possibly shorter device lifetime)—and this problem may get worse as the device's diameter increases. This may pose a problem for devices such as, for example, laser diodes, which need to operate, for example, at several thousand amps per square centimeter. It may also pose an issue for various power devices where currents of hundreds of amperes (amps) may be desired because the lateral current injection may force or necessitate, for example, large distances for the current to travel, or a limited number of device geometries that are possible.

There is thus a need for durable, low-resistance conducting devices as well as for effective methods of fabricating them.

### SUMMARY

In some embodiments, a conductive multi-layer device may be grown and fabricated on an insulating substrate. It may then be separated from the substrate using localized stress regions within/along the conductive layers, resulting from lattice mismatches between layers and from etched surface features. The separated or cleaved layers may be coupled or integrated into a vertical diode structure.

Some embodiments of the invention may provide a conducting device including a plurality of conducting layers, where at least a portion of the conducting layers have a graded material concentration across consecutive layers which produces a lattice mismatch within conducting layers; one or more etched surfaces extending through one or more of the conducting layers, where the etched surfaces create localized stress regions within the conducting layers; where at least a portion of the conducting layers are disposed on an insulating substrate; and where the localized stress regions and the graded lattice mismatch are structurally configured to establish a boundary along which at least a portion of the conducting layers is separable from the insulating substrate.

In some embodiments, the plurality of conducting layers include one or more aluminum gallium nitride (Al₁₋ₓGaₓN) semiconductor layers, and the insulating substrate includes aluminum nitride (AlN).

In some embodiments, the at least one of the plurality of conducting layers is grown pseudomorphically on the insulating substrate.

In some embodiments, the plurality of conducting layers comprise a strained separation layer, which may be an n-type layer thinner than 50 nanometers disposed on the insulating substrate, and which may establish the boundary along which conducting layers may be separated or cleaved from the substrate.

### BRIEF DESCRIPTION OF THE DRAWINGS

Non-limiting examples of embodiments of the disclosure are described below with reference to figures attached hereto. Dimensions of features shown in the figures are chosen for convenience and clarity of presentation and are not necessarily shown to scale. The subject matter regarded as the invention is particularly pointed out and distinctly claimed in the concluding portion of the specification. The invention, however, both as to organization and method of operation, together with objects, features, and advantages thereof, can be understood by reference to the following detailed description when read with the accompanied drawings. Embodiments are illustrated without limitation in the figures, in which like reference numerals may indicate corresponding, analogous, or similar elements, and in which:

FIG. 1 is an example illustration of an example ultraviolet C (UVC) light emitting diode (LED) showing lateral current injections;

FIG. 2 shows an example distribution of stress concentration in example mesa structures or layered devices according to some embodiments of the invention;

FIG. 3 is a schematic diagram showing an example of the pseudomorphic layers that may be grown on an aluminum nitride (AlN) substrate according to some embodiments of the invention;

FIG. 4 is a schematic diagram of an example multi-layer device after deposition of a spreader/passivation layer and deposition of a metal contact and a device handler layer according to some embodiments of the invention;

FIG. 5 is a schematic diagram of an example multi-layer device after separation from an aluminum nitride (AlN) substrate, according to some embodiments of the invention;

FIG. 6 shows an example fabricated conducting device according to some embodiments of the invention;

FIG. 7 shows an example light emitting diode (LED) device according to some embodiments of the invention;

FIG. 8 illustrates example quasi-lateral and vertical diode geometries according to some embodiments of the invention;

FIG. 9 illustrates some example electrical and optical characteristics of an example UVC laser diode according to some embodiments of the invention;

FIG. 10 shows an example distribution of shear stress in an example layered device according to some embodiments of the invention;

FIG. 11 is a plot showing the shear stress at a corner of an example mesa structure as a function of the fillet radius;

FIGS. 12A-C illustrates examples of strained separation layers in mesa structures according to some embodiments of the invention;

FIG. 13 illustrates an example process of connecting and separating active layers to and from substrates, according to some embodiments of the invention;

FIG. 14 illustrates an example process of fabricating a multi Al₁₋ₓGaₓN layer device according to some embodiments of the invention;

FIG. 15 illustrates an example process of fabricating a multi-layer conducting device according to some embodiments of the invention; and

FIG. 16 illustrates an example method of producing a conducting device according to some embodiments of the invention.

It will be appreciated that for simplicity and clarity of illustration, elements shown in the figures have not necessarily been drawn accurately or to scale. For example, the dimensions of some of the elements can be exaggerated relative to other elements for clarity, or several physical components can be included in one functional block or element.

### DETAILED DESCRIPTION

In the following detailed description, numerous specific details are set forth in order to provide a thorough understanding of the invention. However, it will be understood by those skilled in the art that the present invention can be practiced without these specific details. In other instances, well-known methods, procedures, components, modules, units and/or circuits have not been described in detail so as not to obscure the invention.

Some embodiments may relate to making vertical electronic and opto-electronic devices from pseudomorphic semiconductor layers grown on insulating substrates.

According to some embodiments, growing a plurality of conducting layers—such as for example aluminum gallium nitride (Al₁₋ₓGaₓN) semiconductor layers—on a substrate such as, for example, an aluminum nitride (AlN) substrate may allow for developing or fabricating conducting devices such as, for example, UVC laser diodes. Some embodiments of the current invention may provide conducing contact layers (e.g., at the top/bottom of the device) so that the device can be operated in a vertical geometry (as opposed to a lateral geometry, utilizing lateral current injection along conducting layers).

AlN substrates may allow very high quality pseudomorphic epitaxial semiconductor layers of AlN and AlGaN to be grown. However, these substrates are insulating which makes the fabrication of vertical device structures difficult. To remedy this issue, epitaxial layers structures may be removed (and, e.g., be cleaved off) from the insulating substrate in some embodiments of the invention.

As used herein, a natural lattice constant (or simply lattice constant) may refer to a characteristic spacing between atoms in a crystal structure of a given material when it is in its relaxed, strain-free state.

In devices comprising multiple layers formed from materials having different lattice constants, a lattice mismatch may arise, which may be manifested in strain at the interface between the layers—potentially leading to dislocations or defects. For example, in an Al₁₋ₓGaₓN alloy system, varying the aluminum-to-gallium ratio alters the lattice constant, and a mismatch may occur when one composition is grown on another. For instance, AlN has a natural lattice constant of about 3.11 Å, whereas GaN has a natural lattice constant of about 3.19 Å, corresponding to a mismatch of roughly 1−(3.11/3.19)=2.5%, which may result in accumulated strain energy and, if the layer thickness exceeds a critical limit, the formation of misfit dislocations—potentially degrading crystal quality and, e.g., conductive properties.

As used herein, epitaxial growth may refer to the process of depositing a crystalline layer on a crystalline substrate such that the deposited layer follows the crystal orientation of the underlying substrate. Pseudomorphic growth may refer to the growth (e.g., epitaxial growth) of a thin crystalline layer that conforms to the lattice structure of an underlying layer even when their natural lattice constants differ. This effect occurs because the thin layer elastically strains to match the underlying lattice, allowing smooth growth without immediately introducing dislocations or defects.

In some embodiments, pseudomorphic Al₁₋ₓGaₓN layers may be grown on AlN substrates, where the epitaxial layers are grown to mimic the orientation and crystal structure of the substrate beneath them under compressive strain—such that they exactly lattice match the underlying AlN substrate lattice parameter. In some embodiments, n-type Al₁₋ₓGaₓN layers may be grown and disposed on the AlN substrate first, e.g., due to a higher conductivity compared to p-type material for the same Al concentration, although it may also be possible to make devices where the sequence of polarities is reversed. Such pseudomorphic growth may eliminate, or may produce fewer misfit dislocations, and may allow to achieve Al₁₋ₓGaₓN layers with very low (<10⁶ cm⁻²) threading dislocations in the epitaxial layer.

Some embodiments may employ graded material concentration, where, for example, the value of x in Al₁₋ₓGaₓN may be gradually adjusted across consecutive layers (which may be grown, e.g., pseudomorphically, on an appropriate substrate). Such grading may, for example, reduce abrupt lattice mismatch and distribute strain more evenly, supporting more reliable epitaxial growth. Additionally or alternatively, grading may create a shear stress topology within a multi-layer apparatus or device which may be used, for example, to separate conducting layers from an insulating substrate on which they may be grown (e.g., pseudomorphically).

While some embodiments including, inter alia, Al₁₋ₓGaₓN layers with varying x values are described herein as nonlimiting examples, different embodiments may use or employ different sets of layers and/or material compositions.

As used herein, “active” or conductive layers may refer to device layers that participate in electrical conduction or optical activity, in contrast to an insulating substrate, which does not conduct current on which active layers may be grown (e.g., pseudomorphically).

Separating active layers, such as, for example, pseudomorphically grown layers, from an underlying insulating substrate may be desirable because it may enable device integration (such as, e.g., integrating active or conducting layers as a first portion of a diode structure, into a second, different portion of a device or diode structure, etc.). It may also improve thermal management, allow for recycling or reusing of the substrate for additional growth processes, and the like. By removing the substrate (for example via cleaving and using localized stress regions formed by etching and grading of active layers), some embodiments may improve existing fabrication techniques by enabling delicate active films or devices built atop the substrate to be separated intact, which may reduce cost (by reusing the expensive substrate), improve yield (by reducing breakage or waste), and support production of thin-film or flexible device architectures that are lightweight or transferable.

Some embodiments may provide a controlled cleaving process for releasing and transferring active layers without introducing excessive damage or defects, thereby preserving the structural and electronic quality of the active layers while enabling their use in a broader range of device architectures.

In some embodiments, separating active layers from an insulating substrate may involve controlled cleaving processes initiated at specific, localized stress regions on and/or within a multi-layer device or apparatus. In some embodiments, localized stress regions may be formed within a multi-layered conducting device or apparatus depending on or as a result of layer composition and/or grading, and/or of etched surfaces extending through the device's layers.

Some embodiments may improve conducting diode technologies, including UV-C LED applications, by providing conducting layers with low defect densities that can serve as at least a portion of a vertical diode geometry.

As used herein, n-type and p-type layers may refer to layers designed and/or doped with impurities to create an excess of electrons (n-type) or holes (p-type), enabling controlled electrical conductivity. A p-n junction is the interface between these n-type and p-type layers, where charge carriers diffuse and create a depletion region, allowing the device to control current flow.

As used herein, etching may refer a process used to selectively remove material from a semiconductor surface, either chemically or physically, to shape, pattern, or clean the layers during device fabrication. Some nonlimiting example etching techniques that may be used in some embodiments may include Reactive Ion Etching (RIE), a dry etching method using reactive plasma gases like Cl₂, BCl₃, or SF₆, which chemically react with AlGaN to remove material while providing anisotropic (directional) etching; Inductively Coupled Plasma (ICP) Etching, a high-density plasma technique often combined with Cl₂/BCl₃/Ar mixtures, providing high etch rates and good control over vertical sidewalls; Wet Chemical Etching, which uses solutions like KOH, TMAH, or phosphoric acid (H₃PO₄), etch rates can depend strongly on Al content and crystal orientation; and Photoelectrochemical (PEC) Etching, which Involves illuminating AlGaN in a suitable electrolyte to selectively etch regions. Additional or alternative etching techniques and/or processes may be used in different embodiments.

As used herein, a boundary along which active or conducting layers may be cleaved from an insulating substrate may be “structurally established” by the deliberate physical configuration of materials and geometries—for example through epitaxial growth and microfabrication or etching techniques. For example, a boundary along which at least a portion of the conducting layers is separable from the insulating substrate may be structurally established by: (1) etching processes, or introducing or creating etched surfaces such as mesa sidewalls that concentrate mechanical stress and shear forces at specific regions, and (2) graded lattice mismatch, achieved by growing consecutive Al₁₋ₓGaₓN layers with progressively varying Ga content (e.g., different values of X in Al₁₋ₓGaₓN across consecutive layers, which may induce a controlled strain gradient due to the mismatch in lattice constants between the Al₁₋ₓGaₓN layers and the underlying AlN substrate). Alone or in combination, these features may create localized stress regions within or across the plurality of active layers and/or define a mechanically weak interface—i.e., a cleaving plane or boundary—along which the conducting layers may be selectively separated from the insulating substrate (e.g., without compromising the integrity of the active device layers). In some embodiments, the cleaving plane or boundary may be established on a dedicated strained layer, also referred to herein as a strained separation layer.

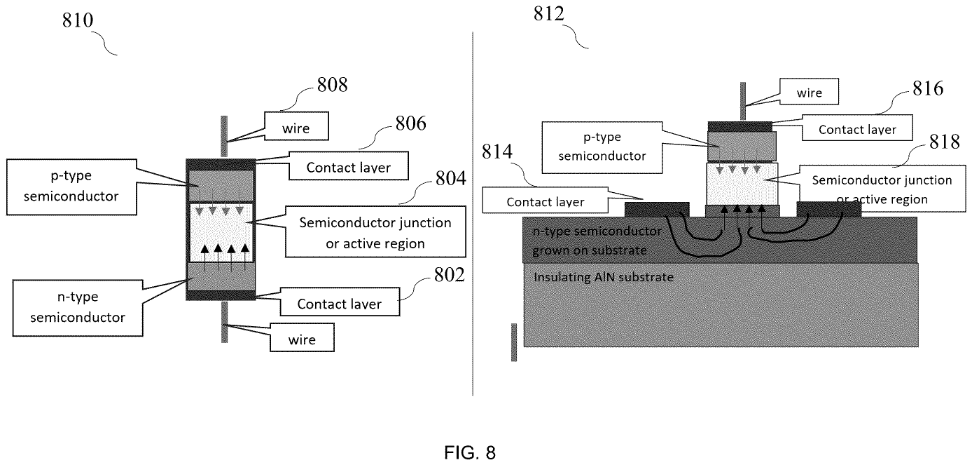

As used herein, a vertical diode may refer to a conducting device in which current flows perpendicularly to a substrate surface—e.g., from a top/bottom contact (see, e.g., element 802 in FIG. 8) through the active layers (element 804) and into the opposite top/bottom contact (element 806)—enabling high current density and efficient energy use. In contrast, a lateral current diode conducts current parallel to the substrate surface (e.g., parallel to the top/bottom contact and to, e.g., wire 808), which can limit current handling and scalability. In a vertical diode according to some embodiments of the invention, a vertical injection path may allow for compact, high-power devices such as UV-C LEDs, where cleaved active layers (which may for example be pseudomorphically on and separated from an insulating substrate using a cleaving process) may be integrated into a vertical stack or diode structure.

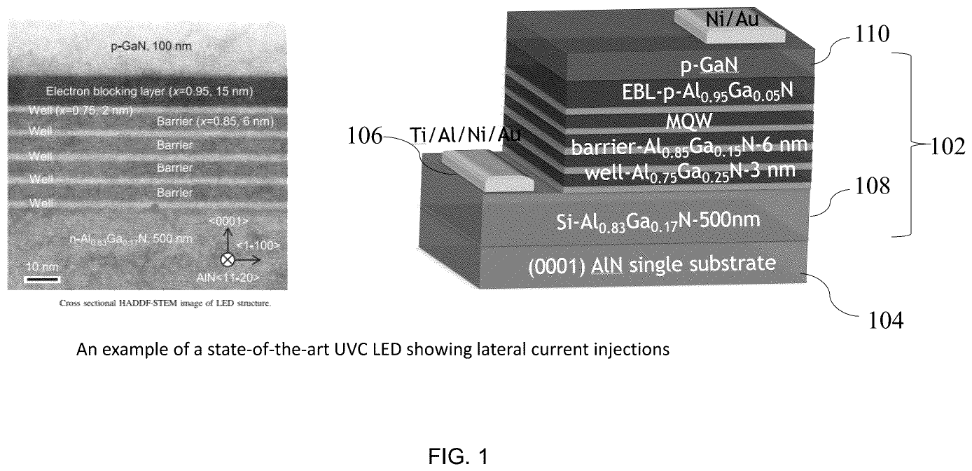

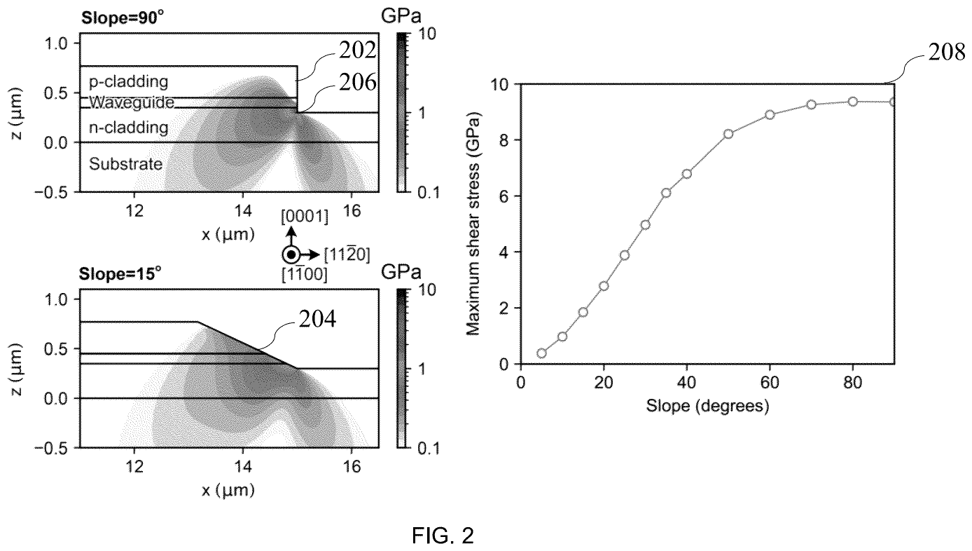

FIG. 1 is an illustration of an example ultraviolet C (UVC) light emitting diode (LED) showing lateral current injections.

A pseudomorphic epitaxial structure 102 may be grown on an insulating AlN substrate 104. N-type contact or, contact to the n-type layer 106 may be made by etching down to that layer and depositing metal contacts on it. In this nonlimiting example, current may be injected laterally into the n-type layer 108 which may proceed to the p-type layer 110.

Graded material concentration may refer to a structural feature in which multiple epitaxial layers are grown sequentially, each with a distinct alloy composition, resulting in a variation in material properties such as, e.g., lattice constant (but possibly also bandgap, and polarization), e.g., across consecutive layers. This approach may allow for controlled strain engineering and stress localization, which is particularly useful in cleaving and device isolation processes. For example, pseudomorphic Al₁₋ₓGaₓN layers may be grown on a c-face AlN substrate with decreasing Ga content (namely, decreasing x value in Al₁₋ₓGaₓN) across consecutive layers: starting with Al_{0·6}Ga_{0·4}N closest to the AlN substrate, followed by Al_{0·7}Ga_{0·3}N, Al_{0·8}Ga_{0·2}N, Al_{0·9}Ga_{0·1}N, etc. Each layer may remain pseudomorphic to the AlN substrate up to its critical thickness, and the cumulative graded lattice mismatch introduces localized stress regions that can be exploited for cleaving or enhancing carrier confinement in device structures.

Some embodiments may include a plurality of conducting layers, at least a portion of the conducting layers having a graded material concentration across consecutive layers, where the grading produces a lattice mismatch within the plurality of conducting layers. In some embodiments, the plurality of conducting layers comprise one or more aluminum gallium nitride (Al₁₋ₓGaₓN) semiconductor layers grown on an aluminum nitride (AlN) substrate.

For example, according to some embodiments, it may be possible to grow relatively thick pseudomorphic Al₁₋ₓGaₓN layers 102 on a c-face AlN substrate 104. These pseudomorphic layers 102 may be strained by the lattice mismatch between Al₁₋ₓGaₓN layers 102 and the AlN substrate 104.

To grow pseudomorphic active layers on an insulating substrate, some embodiments of the invention may employ metal-organic chemical vapor deposition (MOCVD) or molecular beam epitaxy (MBE) under carefully controlled conditions to maintain coherent epitaxial growth despite the lattice mismatch. Al₁₋ₓGaₓN layers may be deposited with a composition gradient or fixed alloy ratio such that the in-plane lattice constant remains strained to match that of the underlying AlN substrate. This strain may be maintained pseudomorphically, without dislocations, up to a critical thickness, beyond which relaxation (and, e.g., loss of the desired stress profile) may occur. The lattice mismatch between an Al₁₋ₓGaₓN alloy and a AlN substrate may introduces biaxial tensile or compressive strain depending on the Ga content, which can be exploited to engineer stress profiles including high stress regions for subsequent layer separation or device isolation. Precise control of ambient conditions may be required to achieve high-quality, defect-minimized pseudomorphic layers suitable for high-performance optoelectronic or power devices according to some embodiments of the invention.

In some embodiments, a plurality of conducting layers may include a p-type layer disposed on another layer of the plurality of conducting layers. In some embodiments, the lattice mismatch may increase with increasing Ga concentration (increasing x) across consecutive layers, to a value of 2.4% for pure or polarization doped GaN (which may be used as a p-type layer 110). As further demonstrated herein, when surfaces extending through these highly strained layers are etched to form mesas (which may refer to a raised, isolated region of a semiconductor layer created by etching away the surrounding material), regions of very high stress may be created at the corners of the etched surfaces or mesas. These very high stress regions may serve as natural cleavage initiation points along the basal plane (c-plane) of the hexagonal nitride crystal.

FIG. 2 shows an example distribution of stress concentration in example mesa structures or layered devices according to some embodiments of the invention.

Some embodiments of the invention may include one or more etched surfaces extending through one or more of the plurality of conducting layers, the etched surfaces creating localized stress regions within the plurality of conducting layers.

Color maps illustrate calculated stress distributions for two example mesa geometries: mesa A 202 with a vertical sidewall or surface (90° slope) and mesa B 204 with a sloped sidewall or surface (15° slope). For mesa A 202, the stress may be locally concentrated at a region or corner 206 of the mesa, while for mesa B 204, the stress may be spread more broadly (may be less localized to a specific region), and have a lower maximum intensity within the mesa. Device layers may include substrate, n-cladding, waveguide, and p-cladding, although additional or alternative layered structures may be used in devices according to different embodiments. Panel 208 shows a plot of maximum shear stress at the mesa or surface edge as a function of sidewall or surface slope. It may be seen that maximum stress increases with slope angle, reaching its highest values near vertical geometries (close to 90°). Additional or alternative geometries may be used in different embodiments.

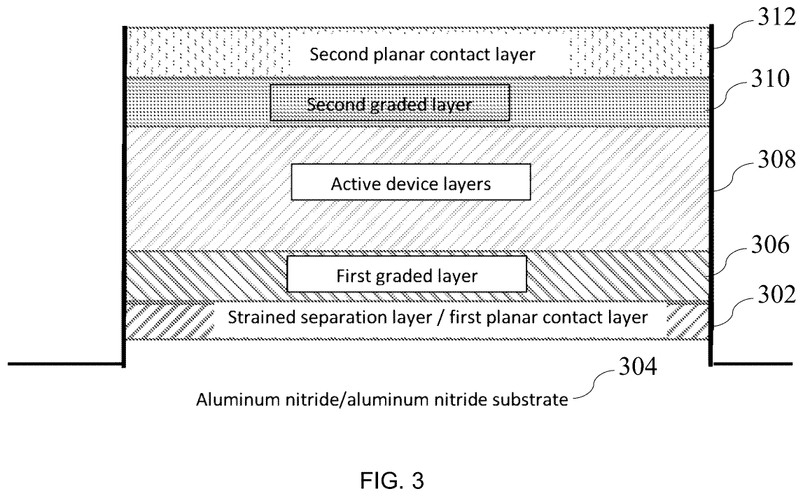

FIG. 3 is a schematic diagram showing an example of the pseudomorphic layers that may be grown on an aluminum nitride (AlN) substrate according to some embodiments of the invention.

According to some embodiments, at least a portion of the plurality of conducting layers are disposed on an insulating substrate. In some embodiments, at least one of the plurality of conducting layers is grown pseudomorphically on the insulating substrate, and plurality of conducting layers may include an n-type layer thinner than 50 nanometers disposed on an insulating substrate.

For example, a Strained Separation Layer 302 may be grown on AlN substrate 304. In some embodiments, Strained Separation Layer 302 may, for example, be a thin layer (e.g., less than 50 nanometers; nm) of pseudomorphic GaN, or an Al₁₋ₓGaₓN layer where the value of x would be as high as possible but still allowing pseudomorphic growth to occur for the entire device structure. In some embodiments, Strained Separation Layer 302 may be doped. In some exemplary embodiments, the doping may be using Si atoms so that Strained Separation Layer 302 may be an n-type layer, and may designed and/or etched to separate active device layers or conducting layers from an insulating substrate through a cleaving process.

There are several ways that the cleavage or cleaving process may be initiated and carried out. For example, heating the mesa structures on the AlN substrate will start the propagation of dislocations along the basal plane.

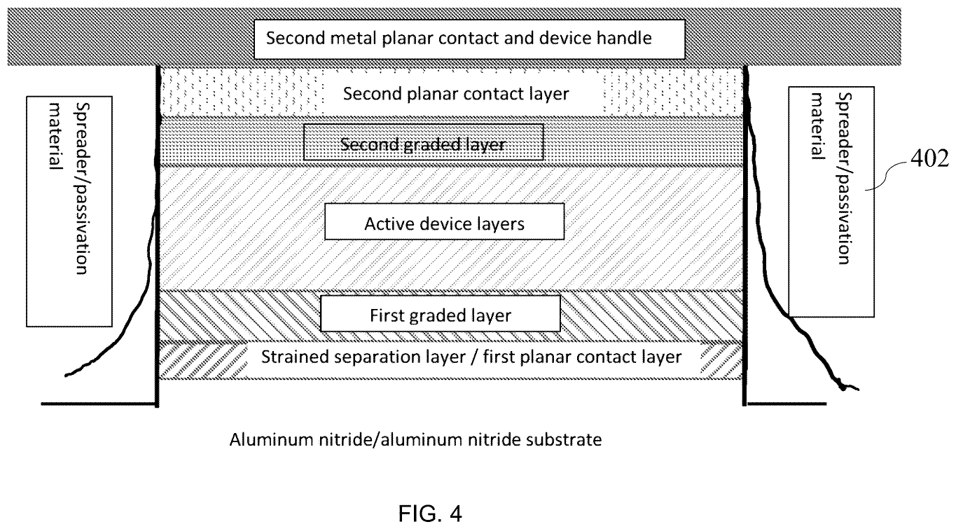

FIG. 4 is a schematic diagram of an example multi-layer device after deposition of a spreader/passivation layer and deposition of a metal contact and a device handler layer according to some embodiments of the invention.

In some embodiments, this initiation of cleavage may be aided by the addition of Spreader Material 402 on the mesa walls (such as for example SiO2 or silicon nitride, or a different passivation material or materials that may be deposited or spun on these walls) and the attachment of the tops of the mesa to a device handler layer/substrate. Both of these structures may stop or prevent the mesa structure from relaxing and will aid the cleavage process.

According to some embodiments, applying a spreader material (such as, e.g., element 402) to one or more of the etched surfaces, and/or attaching one or more portions of the etched surfaces to a second substrate, may mechanically stabilize the structure and prevent relaxation of the localized stress regions and desired stress profile that may define a cleaving boundary. A spreader material, for example, may conformally coat the etched features, maintaining the stress profile induced by graded lattice mismatch across the plurality of conducting layers. Bonding the etched surface to a second substrate via eutectic or adhesive bonding techniques may similarly constrain the structure and preserve the stress gradient, preventing it from relaxing.

Some embodiments may use a laser lift-off process where the laser wavelength may be designed to be absorbed by narrow bandgap Strained Separation Layer. The resulting sudden increase in temperature may initiate cleavage along the AlN/Strained Separation Layer interface.

Another approach would be to use sonic energy, such as, for example, ultrasonic energy to initiate the cleavage process, using sound- or sonic-assisted crack propagation for semiconductor wafering. According to some embodiments, an example process of using ultrasonic energy to initiate controlled cleavage may involve applying an initial mechanical stress to the relevant layers or cleaving region to bring the stress just below its critical value. An ultrasound wave may then be applied to the material or layers, causing the total stress at the cleaving region to exceed the critical value, initiating crack propagation. Some embodiments of the invention take advantage of the fact that location and magnitude of the highest stress point can be controlled by appropriate etching the highly strained epitaxial layers as shown in FIG. 2. Thus, some embodiments enable the initiation of the cleave or crack to be achieved with higher precision and greater reproducibility. Once the crack or cleave is initiated, the frequency and amplitude of the ultrasound wave may be adjusted to maintain a substantially constant and relatively low crack velocity, ensuring controlled propagation. A stress intensity factor K may be monitored to ensure it remains above the critical value K_IC, e.g., to prevent crack arrest and maintain a steady propagation rate. This may allow for precise control over the cleavage process, reducing the risk of uncontrolled cracking and improving the quality of the cleaved material.

In some exemplary embodiments, the Strained Separation Layer may be doped with Si to make it n-type.

According to some embodiments, layer grading may include progressively lower x-values in Al₁₋ₓGaₓN across consecutive layers as distance from the insulating substrate increases.

For example, referring back to FIG. 3, a First Graded Layer 306 may consist of Al₁₋ₓGaₓN (which may or may not be doped with Si to further enhance the n-type conductivity) where x may continuously be graded toward lower x-values as distance from the AlN substrate 304 (the epitaxial growth direction) is increased, which produces a lattice mismatch within the layers. For example, for a c-face, Al-polar surface, grading may increase the electron concentration of First Graded Layer 306, which may be made an even better n-type conductor through, e.g., distributed polarization doping. This polarization doping may improve the device performance, for example by decreasing contact resistance and increasing conductivity through the n-type semiconductor as current may be directed toward a p-n junction in the Active Device Layers 308.

First Graded Layer 306 may also include abrupt junctions or a short-period super lattice which may be disposed or employed to stop possible dislocations from the cleavage process from propagating up into Active Device Layers 308, where they may affect performance or the device's lifetime, or to limit propagation of dislocations upon separation of the plurality of conducting layers from the insulating substrate.

For example, to prevent dislocations or to limit propagation of dislocations generated during the cleavage process from propagating into the active device layers, abrupt junctions or a short-period superlattice (SPSL) can be strategically disposed within the epitaxial stack and may act as dislocation filtering layers by introducing periodic strain fields and interface barriers that impede the vertical motion of threading dislocations. For example, a SPSL composed of, e.g., a plurality of alternating 2-5 nm thick layers of Al_{0·8}Ga_{0·2}N and Al_{0·6}Ga_{0·4}N can be inserted between the strained separation layer or cleaving interface and the remaining epitaxial layers. The lattice mismatch between these layers may create misfit strain that bends or terminates dislocations, reducing their density above the superlattice. Similarly, an abrupt junction, such as for example a sharp transition from Al_{0·9}Ga_{0·1}N to Al_{0·6}Ga_{0·4}N may introduce a localized strain discontinuity that deflects dislocations laterally. These features may be especially critical in UV-C LEDs, where, e.g., dislocation densities above ˜10⁸cm⁻² may significantly degrade internal efficiency and device lifetime. Additional or alternative techniques for limiting propagation of dislocations upon cleaving may be used in different embodiments.

Abrupt junctions may inhibit dislocation propagation (which might affect device performance) by creating a sharp discontinuity in crystal structure or material properties, which requires significant energy for dislocations to cross. Some embodiments may use strained-layer superlattices (SLS) including alternating thin layers of different materials. Some nonlimiting example mechanisms for inhibiting dislocation propagation are described in Table 1:
Lattice mismatch and strain fields
   Strain field creation: A superlattice including alternating layers with different lattice constants, creating a controlled strain field at each abrupt interface.
   Dislocation bending: As a threading dislocation (a dislocation extending from a substrate into an epitaxial film) approaches a strained interface, the high stress field may cause it to bend and propagate laterally. This forces the threading dislocation to become a misfit dislocation at the interface, effectively trapping it and preventing it from propagating further into subsequent layers.
   Annihilation: The high density of bent dislocations at the interface may increase the probability of opposite-sign dislocations encountering and annihilating each other. This may reduce the overall dislocation density in the material layers above the superlattice.
Dislocation blocking and filtering
   Critical thickness: The effectiveness of an SLS may depend on its critical thickness. If a layer exceeds its critical thickness, the built-up strain may be relieved by the formation of new dislocations, diminishing the filtering effect.
   Filtering capacity: A given SLS may have a finite capacity for blocking dislocations. While effective at filtering low dislocation densities, the superlattice may become saturated and less effective at blocking high dislocation densities.
Semiconductor applications of abrupt junctions for dislocation inhibition
   Improving device performance: Dislocation inhibition may be critical for optoelectronic and semiconductor devices, such as lasers and LEDs. The abrupt interfaces may reduce the number of threading dislocations that can act as non-radiative recombination centers, improving the device's efficiency and longevity.
Table 1

In some exemplary embodiments, a Second Graded Layer 310 may be a graded Al₁₋ₓGaₓN layer with x increasing in the growth direction (e.g., in the direction opposite from the First Graded Layer). This may result in a distributed polarization layer of a p-type. This p-type layer structure may aid in the creation of a p-type contact on a Second Planar Contact Layer 312. The Second Planar Contact Layer may, in some embodiments, be a Mg-doped thin GaN layer that may be grown on the Second Graded Layer 310.

According to some embodiments n-type and p-type layers may be used to integrate a multi-layer Al₁₋ₓGaₓN device into a diode structure, such as a UV-C LED. In such a configuration, active layers such as graded Al₁₋ₓGaₓN layers may serve as part of the active region or carrier transport layers. A p-type layer such as AlGaN layer (which may for example be doped with Mg), may be grown or disposed above the active region, while an n-type AlGaN layer, doped with Si, may be grown or disposed below it. Such doped layers may form a p-n junction which may be used in diode operation. When forward biased, electrons and holes may recombine in the active region, emitting UV-C photons. The graded composition across layers may also enhance carrier injection and confinement—which may improve efficiency and, consequently, previous or existing diode architectures.

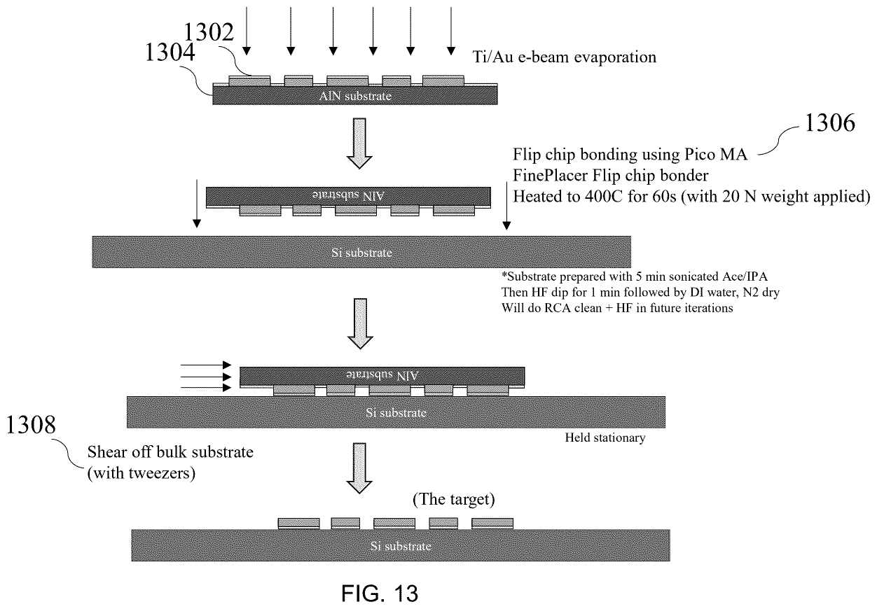

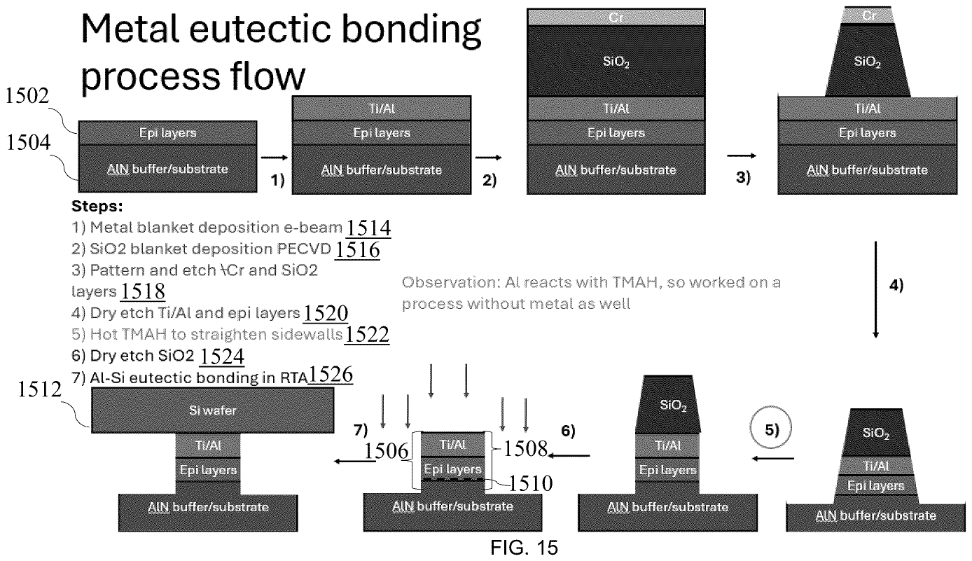

According to some embodiments, active layers cleaved along a boundary (structurally established by a lattice mismatch and etching of the layers) may be integrated into a vertical diode. For example at least a portion of the conducting layers may form the first portion of a vertical diode, which may be transferred and electrically coupled to a second portion of the vertical diode—such as a p-type or n-type layer on a separate wafer (for example by coupling cleaved layers to a target wafer or second substrate—see, e.g., FIGS. 13, 15). In some embodiments, to form a vertical diode structure, contacts between active layers (or the first portion of the diode) to a second portion of the diode may be made, e.g., via an n-type contact and/or p-type contact. This integration allows coupling at least a portion of a vertical diode to the conducting layers separated from the substrate, forming a complete vertical device architecture suitable for high-performance applications such as UV-C LEDs or power electronics. Additional or alternative coupling procedures may be used in different embodiments.

According to some embodiments, a cleaving boundary may be structurally established between a highly strained epitaxial or “epi” layer, and the unstrained substrate or a relatively unstrained epi layer on which the highly strained layer may be disposed. For instance, an epi AlN layer on an AlN substrate may have no strain as long as the substrate is much thicker than the epi layer or layers. According to some embodiments, epitaxial layers may be cleaved or separated along a boundary where the strain between the layers is appropriately large. Once a mesa's surface is etched the strains in the layers may no longer be uniform laterally which may generate the shear stress used to initiate the cleave or crack to separate the layers.

AlN substrates may allow very high quality pseudomorphic epitaxial semiconductor layers of AlN and AlGaN to be grown, however these substrates are insulating which makes the fabrication of vertical device structures very difficult. To remedy this issue, in some embodiments the doped epitaxial layers structures may be removed from the insulating substrate.

For example, according to some embodiments, relatively thick AlGaN layers may be grown pseudomorphically (where the lateral lattice parameter may be compressed to fit exactly the underlying AlN substrate without the formation of misfit dislocations). Even though the strain in these layers may be very high, there may be minimal shear stress to drive cracking or defect formation, except near defects or edges. By growing tailored AlGaN layers and introducing appropriate edge trenches, it may be possible to introduce localized stress regions or high shear stresses near the trench edges which can be used to initiate controlled cleaving along the strained interface.

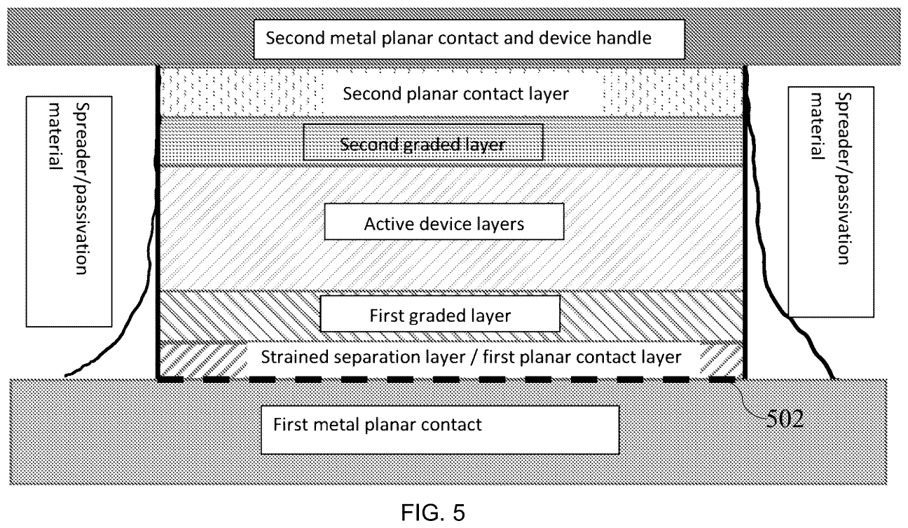

FIG. 5 is a schematic diagram of an example multi-layer device after separation from an aluminum nitride (AlN) substrate, according to some embodiments of the invention.

In some embodiments, a boundary may be formed (e.g., by localized stress regions resulting from the graded lattice mismatch and the etching or the mesa structure) along which at least a portion of the plurality of conducting layers is separable from the insulating substrate. In some embodiments, localized stress regions (created, e.g., by etching device layers to form a mesa with an appropriate angle) and the graded lattice mismatch (resulting from, e.g., differences in lattice constants across pseudomorphically grown layers) may be designed or structurally configured to establish a boundary along which at least a portion of the plurality of conducting layers is separable from the insulating substrate (e.g., by a cleaving process).

In some embodiments the boundary is established between the n-type layer and the insulating substrate. For instance, with appropriate doping and grading, a boundary or cleaved interface 502 may be found or may be established (e.g., prior or during separation from the substrate) on or along a strained separation layer. In some embodiments the strained separation layer may be an n-type layer structurally configured (e.g., etched and/or including a material concentration or composition) to include localized stress regions and/or a lattice mismatch using which the boundary or interface 502 may be established. In some embodiments, the boundary or interface may be established between an n-type strained separation layer and an insulating substrate. For example, cleaved interface 502 may result from a cleaving process separating active device layers 308 from insulating AlN substrate 304. In some embodiments, cleaved interface 502 may be used, e.g., to make an n-contact to a vertical AlN diode structure. Thermal and/or sonic approaches to initiating the cleave along the strained interface may be used in different embodiments.

An example process flow for producing an example multi-layer vertical device according to some embodiments of the invention may include, (1) pseudomorphic AlN and AlGaN structures or layers may be grown on AlN substrate (see FIG. 3) followed by etching surfaces of the device to create localized stress regions within the layers and/or attaching of metal handle to act as contact and support for device structure (e.g., see FIG. 4). The substrate may be removed, and the bottom contact may be fabricated (FIG. 5).

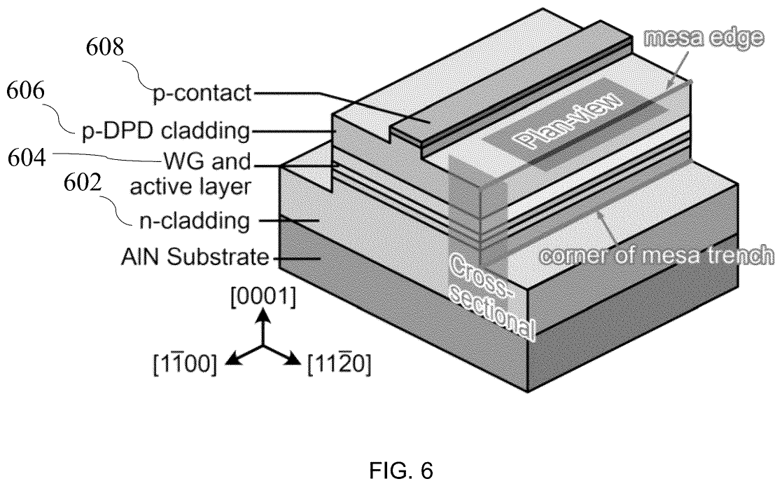

FIG. 6 shows an example fabricated conducting device according to some embodiments of the invention. In this nonlimiting example, AlGaN-based UVC LED structures may be grown on single-crystal AlN substrates using metal organic vapor phase epitaxy. An example UVC LED may include, for instance, 350 nanometer (nm) thick n-type Al_{0.7}Ga_{0.3}N n-clad layer 602, a 100-nm thick Al_{0.63}Ga_{0.37}N waveguide layer with multiple quantum wells 604, a 320-nm-thick p-type distributed-polarization doped (p-DPD) cladding layer 606 with an average Al composition of 0.85, and a p-contact layer 608. A dry etching process using Cl gas may be employed to isolate a p-contact layer for current narrowing while simultaneously forming mesa stripes along the [1100] direction (see coordinate system in drawing).

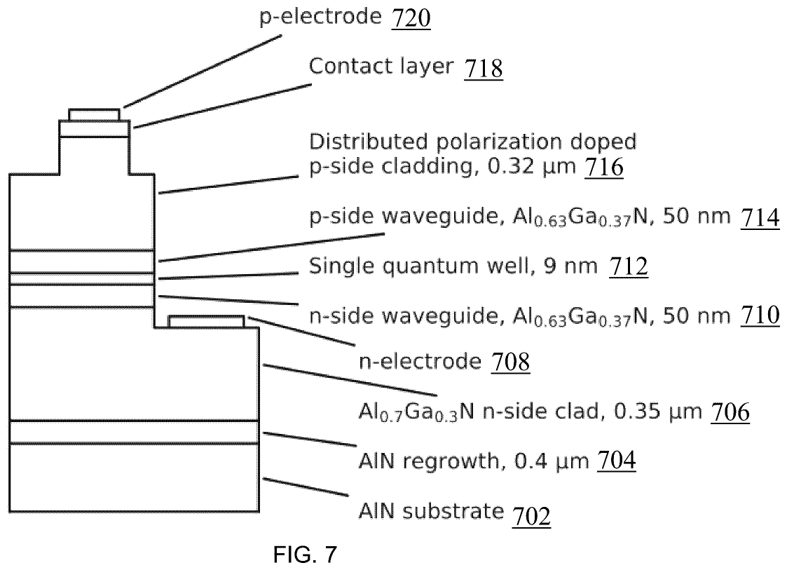

FIG. 7 shows an example light emitting diode (LED) device according to some embodiments of the invention. According to some embodiments a layered light-emitting device structure may be formed on a substrate and may include a plurality of conducting layers. For example, a lower portion of the structure may comprise an aluminum nitride (AlN) substrate 702, above which an AlN regrowth layer 704 may be disposed. An n-type cladding region 706 such as an Al_{0·7}Ga_{0·3}N layer may follow, along with an n-side electrode 708 for electrical connection. Above the cladding, the example device may include an n-side waveguide layer 710, a quantum well region (such as, e.g., a thin single quantum well 712), and a p-side waveguide layer 714. A p-side cladding layer 716, which may be polarization-doped, may be disposed above p-side waveguide layer 714. Toward the upper portion of the device, a contact layer 718 and a p-side electrode 720 may be formed. While the nonlimiting example shown is that of a quasi-lateral geometry, different embodiments may use a vertical diode geometry. Additional or alternative layered conducting structures may be used in different embodiments.

FIG. 8 illustrates example quasi-lateral and vertical diode geometries according to some embodiments of the invention. Two terminal devices (such as, e.g., diodes or resistors) may work best in a vertical arrangement (element 810), where current may flow along a single axis (namely, vertically, along the axis of wire 808), e.g., through and from the n-type contact layer 802 towards the p-type contact layer 806 and though the p-n junction or active region 804. However, previous and existing devices on AlN substrates have relied on lateral current injection because of the insulating nature of the AlN substates. In a lateral or quasi-lateral geometry (element 812), current may be injected through the n-type contact 814 and has to flow laterally (e.g., along and not only through the plane of a conducting layer) under the device before it can flow vertically up, towards the p-type contact 816 and though the p-n junction or active region 818. An n-type Al₁₋ₓGaₓN material is grown first because it may have a higher conductivity when compared to p-type material for the same Al concentration but it is also possible to make devices where the sequence of polarities is reversed.

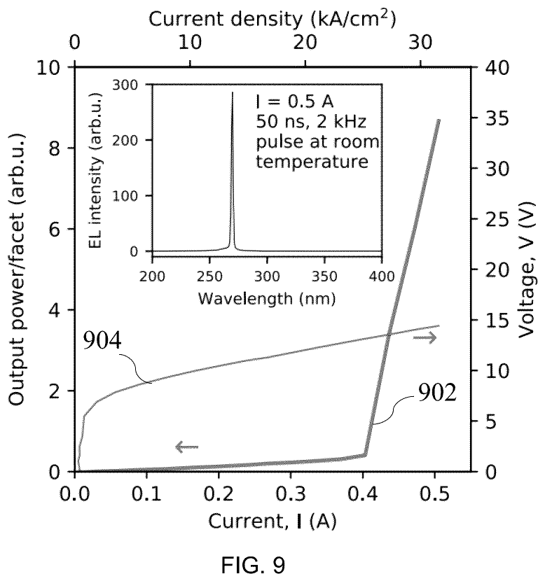

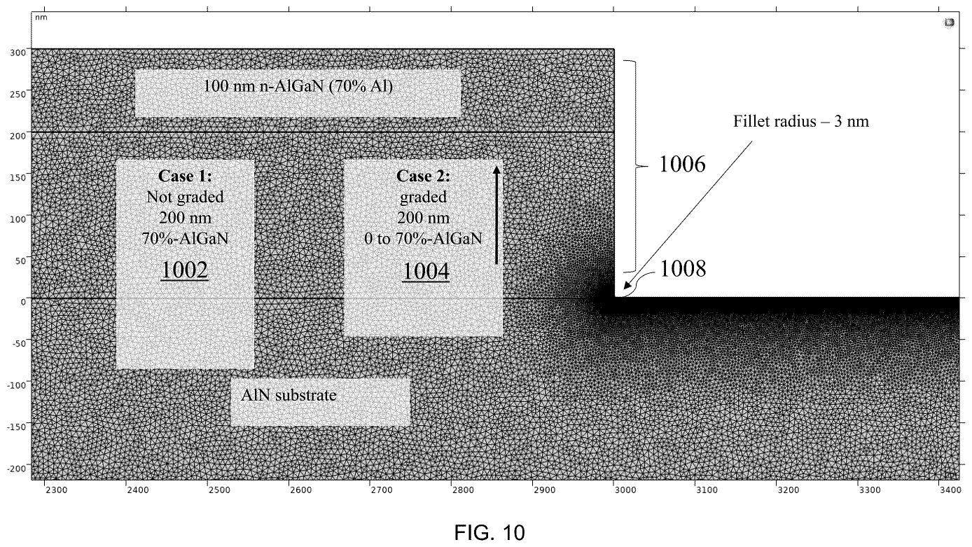

FIG. 9 illustrates some example electrical and optical characteristics of an example UVC laser diode according to some embodiments of the invention. Some example conducting devices according to some embodiments may exhibit current-voltage (I-V) behavior where, for example, a nonlinear increase of the output power may be observed at a current above a threshold, or a threshold current I of 0.4 ampere (A) (see power vs. current curve 902). In this nonlimiting example, a sharp lasing spectrum peak appears at ˜271 nm given a current higher than the threshold or above the threshold current. The operating voltage at the threshold current is shown to be ˜13.8 V (see voltage vs. current curve 904). Additional or alternative UVC laser diodes, having different electrical/optical characteristics, may be produced or provided in different embodiments.

FIG. 10 shows an example distribution of shear stress in an example layered device according to some embodiments of the invention. According to some embodiments, a semiconductor stack including conducting layers of AlGaN may be formed on top of an insulating AlN substrate. Two cases may be considered. Case 1 1002 includes a uniform 200 nm Al_{0·7}Ga_{0·3}N active layer and case 2 1004 includes a 200 nm region having a graded material concentration across consecutive active layers from 0% to 70% Al content. Above these a 100 nm n-AlGaN conducting layer (70% Al) may be deposited. The structure highlights the role of lattice mismatch between AlGaN and the AlN substrate, where material concentration and grading, as well as the etching of layer surfaces or boundaries 1006 may be used to introduce controlled stress (e.g., in the high stress region or corner 1008). In the depicted example, layer grading and the etching of active layers as per case 2 1004 results in high stress region with a 3 nm fillet radius-determining the local stress distribution and device performance.

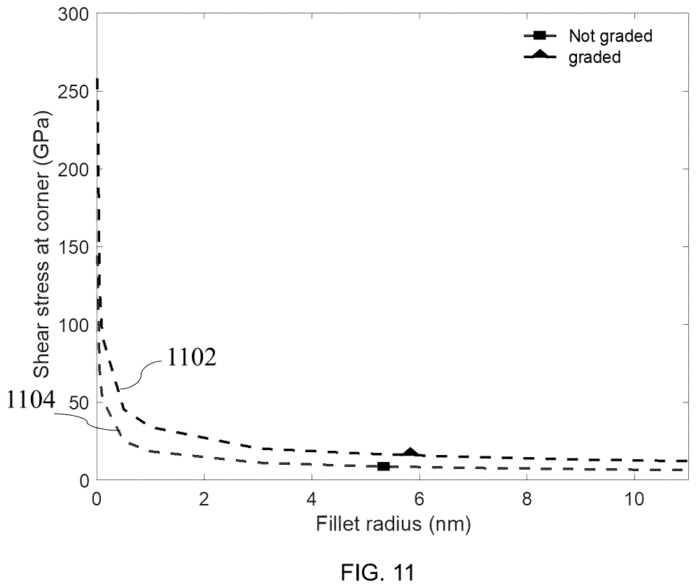

FIG. 11 is a plot showing the shear stress at a corner of an example mesa structure as a function of the fillet radius. For the two different structures described in FIG. 10, it can be seen that the shear stress values (in giga pascal, GPa) for fillet radii above ˜0.5 nm are consistently higher for graded devices (curve A 1102) as compared to non-graded devices (curve B 1104). While the corners defined by etching naturally act as localized stress regions, the magnitude of the stress is controlled by the epitaxial structure for a given fillet radius. While rounding the fillet radius appears to reduce stress concentration (as can be seen for larger fillet radii), graded layers still exhibit elevated shear stress relative to non-graded structures across the displayed radius range.

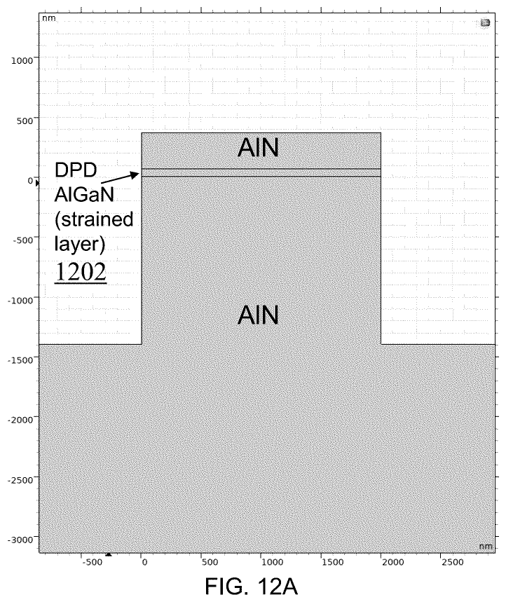

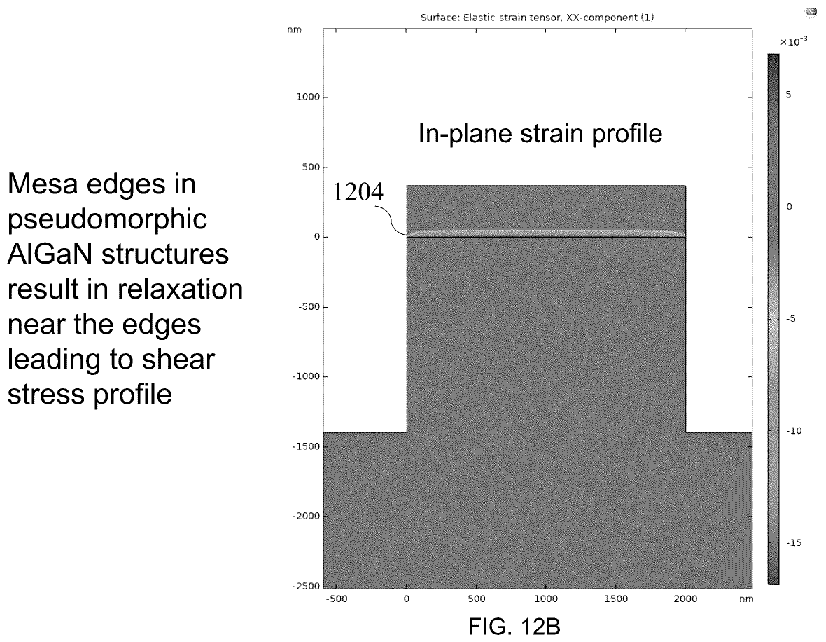

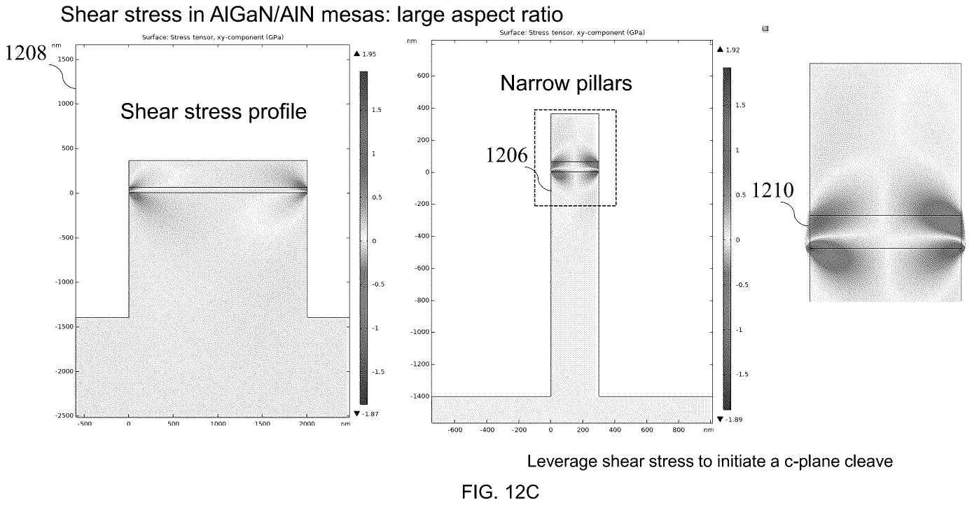

FIGS. 12A-C illustrates examples of strained separation layers in mesa structures according to some embodiments of the invention. FIG. 12A illustrates an example Distributed Polarization Doped (DPD) AlGaN strained separation layer deposited between AlN substrates according to some embodiments of the invention. An example mesa structure according to some embodiments may include a plurality of conducting layers formed atop an insulating substrate, with a strained layer 1202 (of, e.g., DPD AlGaN) designed to facilitate separation from the insulating substrate.

FIG. 12B illustrates an in-plane strain profile within an example mesa structure according to some embodiments of the invention. Mesa etching and layer grading (resulting in, e.g., a lattice mismatch) may induce localized stress regions within strained separation layer 1204.

FIG. 12C shows a large aspect ratio of stress profiles in example mesa structures according to some embodiments of the invention. Stress regions such as for example shown in FIG. 12B, particularly shear stress concentrated near mesa edges and within narrow, high-aspect-ratio pillars 1206, enable controlled detachment of strained layers such as, e.g., layers 1202 and 1204, and of the active layers above it, from the insulating substrate. The in-plane strain and shear stress profiles 1208, 1210 shown in the figures highlight how relaxation at the mesa edges contributes to initiating a c-plane cleave, which may be used for, e.g., device isolation and layer transfer.

FIG. 13 illustrates an example process of connecting and separating active layers to and from substrates, according to some embodiments of the invention. According to some embodiments, conducting layers 1302 may be deposited on an insulating substrate (such as, e.g., AlN; element 1304), and Si substrate or wafer may be attached to the top conducting layer, e.g., through flip-chip bonding (element 1306). A cleaving process along a boundary, where the boundary may be established, e.g., by mesa etching and layer grading that create localized stress regions, may be used to mechanically separate the active layers from the bulk insulating substrate (element 1308). The transferred layers on Si may enable the fabrication of devices such as a vertical diode, with the conducting layers supported by the newly bonded substrate and the insulating substrate removed. Additional or alternative processes or process steps may be used in different embodiments.

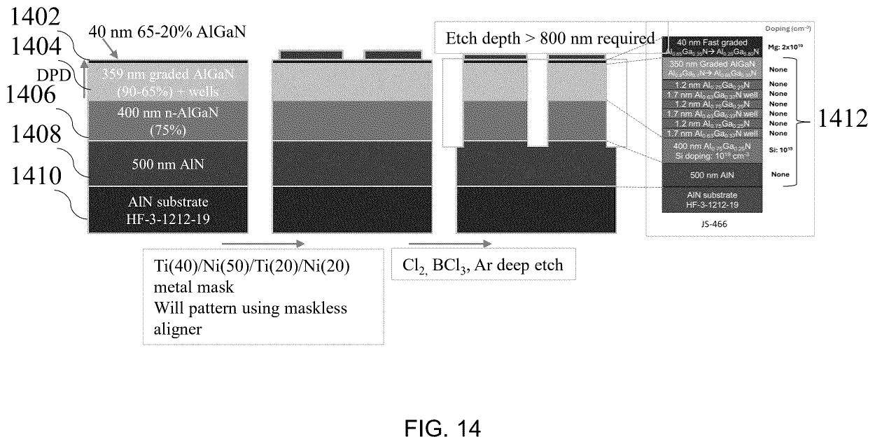

FIG. 14 illustrates an example process of fabricating a multi Al₁₋ₓGaₓN layer device according to some embodiments of the invention. A vertical diode structure according to some embodiments may include a plurality of conducting layers, including, e.g., a 40 nm AlGaN layer (65-20% Al) 1402, disposed or deposited on top of a 359 nm graded AlGaN layer (90-65%) with wells 1404, a 400 nm n-AlGaN layer (75%) 1406, and a 500 nm AlN 1408, all deposited on an insulating AlN substrate (HF-3-1212-19) 1410. A cleaving process may be carried out (e.g., along a boundary structurally established by or resulting from mesa etching and layer grading) which induces localized stress regions that may facilitate the separation of layer 1408 (or of active layers 1412) from the insulating substrate 1410. Metal masks composed of Ti/Ni stacks may be patterned using a maskless aligner, and deep etching with Cl2, BCl3, and Ar gases may be used to achieve an etch depth exceeding 800 nm, which may be required to create localized stress for the cleaving process. Additional or alternative processes or process steps, as well as layer compositions, may be included in different embodiments.

FIG. 15 illustrates an example process of fabricating a multi-layer conducting device according to some embodiments of the invention. The process may begin with the depositing or growing of epitaxial active layers 1502 (e.g., pseudomorphically) on an insulating AlN substrate 1504, followed by a series of etching steps—resulting in etched surfaces (e.g., surfaces 1506, 1508) and shaping of the device. These etched surfaces, in combination with layer grading that introduces a graded lattice mismatch, may structurally establish localized stress regions within the stack. These stress regions are structurally configured to establish a cleaving boundary 510 along which layers, such as, e.g., a strained separation layer and active layers deposited atop of it, may be separated from the insulating AlN substrate 1504. The conducting layers may be coupled to a vertical diode structure—for example through separate Si wafer 1512 and via an n-type contact, enabling electrical integration.

In some embodiments, the vertical diode may be electrically coupled to the cleaved region, or to a region or boundary previously cleaved from a substrate (e.g., by a cleaving process initiated at localized stress regions within a strained separation layer or different layers).

Nonlimiting example layer deposition, grading and etching processes (including, e.g., Ti/Al Metal blanket deposition by e-beam 1514, as well as SiO2 and Cr blanket deposition via Plasma-Enhanced Chemical Vapor Deposition (PECVD) 1516 for example to constrain and localize stress along/within epitaxial layers 1502; patterning and etching of Cr and SiO₂ layers 1518, dry etching of Ti/Al and epitaxial layers 1520, and hot Tetramethylammonium Hydroxide (TMAH) treatment to straighten sidewalls 1522 and to form narrow pillars; dry etching and removal of the SiO₂ 1524 layer to allow coupling the structure to Si wafer 1512, and the like) may be carried out to facilitate precise layer transfer, and eventual bonding and electrically coupling the active layers to a diode structure or device (e.g., through Al—Si eutectic bonding to a Si wafer in a rapid thermal annealing (RTA) process 1526), as well as to facilitate controlled cleaving from AlN substrate 1504. This integration may support high-performance device fabrication while maintaining structural and electrical continuity across the cleaved interface. These nonlimiting example operations or steps may be used to define the entire stack into ˜300 nm diameter pillars, which may serve to localize mechanical stress and enhance ultrasonic energy coupling during separation.

Additional or alternative processes or process steps may be used in different embodiments.

In a nonlimiting example embodiment of the invention, a multilayer Al₁₋ₓGaₓN structure comprising a plurality of active layers—including a strained separation layer—may be grown pseudomorphically on an insulating AlN substrate to enable ultrasonic-assisted cleaving. The grown structure may begin with a thin (<50 nm) n-type GaN separation layer (which may, e.g., be polarization doped), which may be compositionally and electrically distinct from other active layers and may structurally establish a stress and conductivity profile and boundary along which the active layers may be cleaved or separated from the insulating substrate. Above the strained separation layer, 200 nm-thick layers of Al₁₋ₓGaₓN layer (see, e.g., element 1004 of FIG. 10) may be grown pseudomorphically and graded from x=0 to x=0.7, inducing a lattice mismatch of ˜2.5% between layers. The entire stack may be etched into 300 nm diameter pillars to localize stress and enhance ultrasonic energy coupling. The resulting, etched mesa structure would have a compressive stress profile within the active layers, including stress values of up to ˜3-4 gigapascal (GPa). This stress may be concentrated near corners of the etched device or mesa structures and specifically within the strained separation layer (see nonlimiting example in FIGS. 12A-C), facilitating crack propagation along its interface. Ultrasonic separation may be achieved, for example, using frequencies of 2-5 megahertz (MHz), power densities of 2-8 W/cm², and pulse durations of 50-300 microseconds (μs) to initiate and guide crack propagation along the strained separation layer, enabling clean lift-off of the active layers for reuse or integration.

Additional or alternative parameters/concentrations may be used in different embodiments.

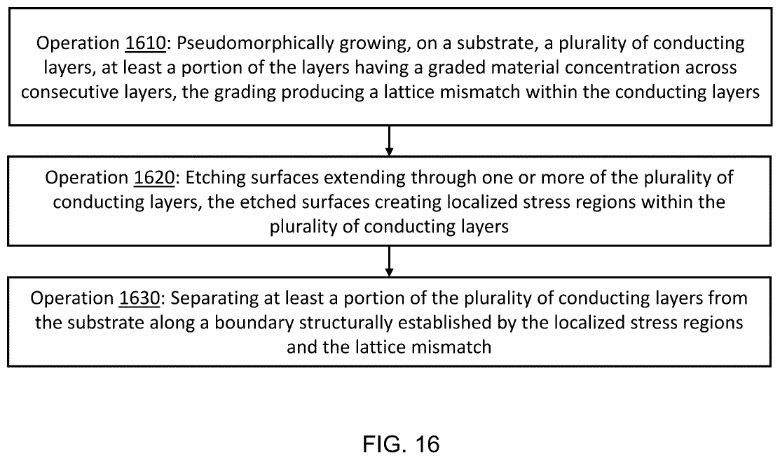

FIG. 16 illustrates an example method of producing a conducting device according to some embodiments of the invention. According to some embodiments, a plurality of conducting layers may be pseudomorphically grown on a substrate - where at least a portion of the plurality of conducting layers may have a graded material concentration across consecutive layers (e.g., a value of x in Al₁₋ₓGaₓN may be gradually adjusted across consecutive layers) which may produce a lattice mismatch (and a corresponding, characteristic stress profile) within the plurality of conducting layers (operation 1610). One or more surfaces extending through conducting layers may be etched, which may create localized stress regions and further create a characteristic stress profile within the plurality of conducting layers (e.g., in combination with the stress created by the lattice mismatch across layers; operation 1620). At least a portion of the conducting layers may then be separated from the substrate along a boundary structurally established by the localized stress regions and the produced lattice mismatch (e.g., along a strained separation layer disposed on the insulating substrate and, e.g., using a cleaving process; operation 1630).

Additional or alternative operations may be used in different embodiments.

The invention is not defined by or limited to the specific embodiments described herein, and various modifications, equivalents, and alternatives may be employed without departing from the scope and spirit of the invention as set forth in the appended claims.

Some embodiments may provide conducting device comprising: an insulating substrate; a plurality of conducting layers, at least a portion of the plurality of conducting layers having a graded material concentration across consecutive layers, the grading producing a lattice mismatch within the plurality of conducting layers; and one or more etched surfaces extending through one or more of the plurality of conducting layers, the etched surfaces creating localized stress regions within the plurality of conducting layers; wherein at least a portion of the plurality of conducting layers are disposed on the insulating substrate; and wherein the localized stress regions and the graded lattice mismatch are structurally configured to establish a boundary along which at least a portion of the plurality of conducting layers is separable from the insulating substrate.

In some embodiments, the plurality of conducting layers comprise one or more aluminum gallium nitride (Al₁₋ₓGaₓN) semiconductor layers.

In some embodiments, the insulating substrate comprises aluminum nitride (AlN).

In some embodiments, the plurality of conducting layers comprise an n-type layer thinner than 50 nanometers disposed on the insulating substrate.

In some embodiments, the boundary is established between the n-type layer and the insulating substrate.

In some embodiments, the grading comprises progressively lower x-values in Al₁₋ₓGaₓN across consecutive layers as distance from the insulating substrate increases.

In some embodiments, the plurality of conducting layers comprise a p-type layer disposed on another layer of the plurality of conducting layers.

In some embodiments at least one of the plurality of conducting layers is grown pseudomorphically on the insulating substrate.

In some embodiments, one or more of the plurality of conducting layers comprise abrupt junctions or a short-period superlattice, the abrupt junctions or the short-period superlattice being disposed to limit propagation of dislocations upon separation of the plurality of conducting layers from the insulating substrate.

Some embodiments may provide a conducting device comprising: a plurality of conducting layers forming a first portion of a vertical diode, at least a portion of the plurality of conducting layers having a graded material concentration across consecutive layers, the grading producing a lattice mismatch within the plurality of conducting layers; a cleaved region extending across one or more of the plurality of conducting layers, the cleaved region defining a boundary along which at least a portion of the plurality of conducting layers have been separated from an insulating substrate; and a second portion of the vertical diode electrically coupled to the cleaved region through an n-type contact.

Some embodiments may provide a method of producing a conducting device, comprising: pseudomorphically growing, on a substrate, a plurality of conducting layers, at least a portion of the plurality of conducting layers having a graded material concentration across consecutive layers, the grading producing a lattice mismatch within the plurality of conducting layers; etching one or more surfaces extending through one or more of the plurality of conducting layers, the etched surfaces creating localized stress regions within the plurality of conducting layers; and separating at least a portion of the plurality of conducting layers from the substrate along a boundary structurally established by the localized stress regions and the produced lattice mismatch.

In some embodiments, the separating comprises initiating cleaving along the boundary, the initiating including one or more of: heating one or more of the etched surfaces, performing a laser lift-off process, and performing a sonic-assisted crack propagation process.

Some embodiments may include applying a spreader material to one or more of the etched surfaces or attaching one or more portions of the etched surfaces to a second substrate, the applied spreader material or the attached second substrate preventing relaxation of the localized stress regions.

Some embodiments may include electrically coupling at least a portion of a vertical diode to the conducting layers separated from the substrate through an n-type contact.

Some embodiments may provide an opto-electronic or electronic device comprising: a first planar contact layer having a first polarity; a second planar contact layer having a second polarity opposite the first polarity layer; layers of nitride semiconductors disposed between the first and the second contact layer which form at least one p-n junction and where all of the semiconductor layers disposed between the first and second contact layer have threading dislocation densities below, e.g., 106 cm⁻²; a first electrical contact disposed in direct mechanical contact with the first contact layer; and a second electrical contact disposed in direct mechanical contact with the second contact layer.

In some embodiments, the first planar contact layer and the second planar contact layer are Al₁₋ₓGaₓN semiconductor layers.

In some embodiments, the layers of nitride semiconductors disposed between the first and second contact layer are Al₁₋ₓGaₓN semiconductor layers.

In some embodiments, at least one of the nitride semiconductor layers is an Al₁₋ₓGaₓN, where x is less than 0.3.

In some embodiments, at least one of the nitride semiconductor layers is an Al₁₋ₓGaₓN, where x is less than 0.15.

In some embodiments, the device emits light out the side of the device in a direction that is more than 30^{o} away from the axis defined by a normal axis intersecting the planes of the two planar contacts.

In some embodiments, the wavelength of the emitted radiation is peaked at wavelength shorter than 235 nm.

In some embodiments, the device may be run at a current density exceeding, e.g., 300 kA-cm−2 while achieving an L70 lifetime exceeding 1,000 hours.

In some embodiments, the device is a laser diode.

In some embodiments, the device is a UVC laser diode with peak emission wavelength shorter than 275 nm.

Some embodiments may provide a method by which a structure consisting of thin layers of Al₁₋ₓGaₓN semiconductor grown by pseudomorphic epitaxy on an insulating AlN substrate can be removed and have a conducting contact layer exposed as a result of the removal process.

Some embodiments may provide a method of manufacturing an AlN structure, comprising, growing Pseudomorphic AlN and AlGaN structures on an AlN substrate; etching and attaching of metal handle to act as contact and support for device structure; and removing the substrate and fabricating the bottom contact.

Some embodiments may provide an opto-electronic or electronic device comprising a first planar contact layer having a first polarity (e.g., an n-type layer); a second planar contact layer having a second polarity opposite the first polarity layer (e.g., a p-type layer); layers of nitride semiconductors disposed between the first and the second contact layer which form at least one p-n junction, where all of the semiconductor layers disposed between the first and second contact layer have threading dislocation densities below, e.g., 10⁶cm⁻²; a first electrical contact (e.g., an n-type contact) disposed in direct mechanical contact with the first contact layer; and a second electrical contact (e.g., a p-type contact) disposed in direct mechanical contact with the second contact layer.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

One skilled in the art will realize the invention may be embodied in other specific forms without departing from the spirit or essential characteristics thereof. The embodiments described herein are therefore to be considered in all respects illustrative rather than limiting. In detailed description, numerous specific details are set forth in order to provide an understanding of the invention. However, it will be understood by those skilled in the art that the invention can be practiced without these specific details. In other instances, well-known methods, procedures, and components, modules, units and/or circuits have not been described in detail so as not to obscure the invention.

Embodiments may include different combinations of features noted in the described embodiments, and features or elements described with respect to one embodiment or flowchart can be combined with or used with features or elements described with respect to other embodiments.

What is claimed is:

1. A conducting device comprising:
an insulating substrate;
a plurality of conducting layers, at least a portion of the plurality of conducting layers having a graded material concentration across consecutive layers, the grading producing a lattice mismatch within the plurality of conducting layers; and
one or more etched surfaces extending through one or more of the plurality of conducting layers, the etched surfaces creating localized stress regions within the plurality of conducting layers;
wherein at least a portion of the plurality of conducting layers are disposed on the insulating substrate; and
wherein the localized stress regions and the graded lattice mismatch are structurally configured to establish a boundary along which at least a portion of the plurality of conducting layers is separable from the insulating substrate.

2. The device of claim 1, wherein the plurality of conducting layers comprise one or more aluminum gallium nitride (Al₁₋ₓGaₓN) semiconductor layers.

3. The device of claim 1, wherein the insulating substrate comprises aluminum nitride (AlN).

4. The device of claim 1, wherein the plurality of conducting layers comprise an n-type layer thinner than 50 nanometers disposed on the insulating substrate.

5. The device of claim 4, wherein the boundary is established between the n-type layer and the insulating substrate.

6. The device of claim 2, wherein the grading comprises progressively lower x-values in Al₁₋ₓGaₓN across consecutive layers as distance from the insulating substrate increases.

7. The device of claim 1, wherein the plurality of conducting layers comprise a p-type layer disposed on another layer of the plurality of conducting layers.

8. The device of claim 1, wherein at least one of the plurality of conducting layers is grown pseudomorphically on the insulating substrate.

9. The device of claim 1, wherein one or more of the plurality of conducting layers comprise abrupt junctions or a short-period superlattice, the abrupt junctions or the short-period superlattice being disposed to limit propagation of dislocations upon separation of the plurality of conducting layers from the insulating substrate.

10. A vertical diode comprising:
a plurality of conducting layers forming a first portion of the vertical diode, at least a portion of the plurality of conducting layers having a graded material concentration across consecutive layers, the grading producing a lattice mismatch within the plurality of conducting layers;
a cleaved region extending across one or more of the plurality of conducting layers, the cleaved region defining a boundary along which at least a portion of the plurality of conducting layers have been separated from an insulating substrate; and
a second portion of the vertical diode electrically coupled to the cleaved region through an n-type contact.

11. A method of producing a conducting device, comprising:
pseudomorphically growing, on a substrate, a plurality of conducting layers, at least a portion of the plurality of conducting layers having a graded material concentration across consecutive layers, the grading producing a lattice mismatch within the plurality of conducting layers;
etching one or more surfaces extending through one or more of the plurality of conducting layers, the etched surfaces creating localized stress regions within the plurality of conducting layers; and
separating at least a portion of the plurality of conducting layers from the substrate along a boundary structurally established by the localized stress regions and the produced lattice mismatch.

12. The method of claim 11, wherein the separating comprises initiating cleaving along the boundary, the initiating including one or more of: heating one or more of the etched surfaces, performing a laser lift-off process, and performing a sonic-assisted crack propagation process.

13. The method of claim 12, comprising: applying a spreader material to one or more of the etched surfaces or attaching one or more portions of the etched surfaces to a second substrate, the applied spreader material or the attached second substrate preventing relaxation of the localized stress regions.

14. The method of claim 11, comprising: electrically coupling at least a portion of a vertical diode to the conducting layers separated from the substrate through an n-type contact.

15. The method of claim 11, wherein the plurality of conducting layers comprise one or more aluminum gallium nitride (Al₁₋ₓGaₓN) semiconductor layers.

16. The method of claim 11, wherein the substrate comprises aluminum nitride (AlN).

17. The method of claim 11, wherein the plurality of conducting layers comprise an n-type layer thinner than 50 nanometers disposed on the substrate.

18. The method of claim 17, wherein the boundary is established between the n-type layer and the substrate.

19. The method of claim 15, wherein the grading comprises progressively lower x-values in Al₁₋ₓGaₓN across consecutive layers as distance from the substrate increases.

20. The method of claim 11, wherein the plurality of conducting layers comprise a p-type layer disposed on another layer of the plurality of conducting layers.
